(19) United States
(12) Patent Application Publication
(10) Pub. No.: US 2009/0317554 A1
(43) Pub. Date: Dec. 24, 2009

(54) APPARATUS AND METHOD FOR SPRAY COATING

(75) Inventors: Dennis R. Christensen, Carmel, IN (US); Imran Ahmad, Plainfield, IN (US); Joseph Wayne Brickell, Westfield, IN (US)

Correspondence Address: LANDO & ANASTASI, LLP, ONE MAIN STREET, SUITE 1100, CAMBRIDGE, MA, 02142, US

(73) Assignee: SPECIALTY COATING SYSTEMS, INC., Indianapolis, IN (US)

(21) Appl. No.: 12/144,971

(22) Filed: Jun. 24, 2008

(51) Int. Cl. B05D 1/02; B05C 11/00

(52) U.S. Cl. 427/427.2; 118/696

(57) ABSTRACT

A spray coating apparatus for spraying material on a substrate includes a frame and a gantry coupled to the frame. The gantry may be configured to provide x-axis, y-axis and z-axis movement. A device is coupled to the gantry. The device may be configured to rotate about the z-axis and pivot about a point on the z-axis. A spray head is coupled to the device. A controller is coupled to the gantry and the spray head. The controller may be configured to control the automated movement of the gantry to provide x-axis, y-axis and z-axis movement and rotational and pivoting movement of the spray head. Other embodiments of the spray coating device and related methods are further disclosed.

### BACKGROUND OF THE INVENTION

1. Field of the Invention

The present disclosure relates generally to apparatus and methods for spray coating materials on a substrate, e.g., electronic substrates, and more particularly to an apparatus and related methods for precisely spray coating such materials on substrates.

2. Discussion of Related Art

Spray coating apparatus are well known in the art. Such apparatus may be configured to spray a variety of solvent-based, water-based and solid coatings onto substrates. When dispensing materials on electronic substrates, such as printed circuit (or wiring) boards, accuracy and functionality are important considerations. Typical coating apparatus include a spray coating head that is mounted on a gantry capable of providing three axes of movement, i.e., x-axis, y-axis and z-axis movement. The movement of the spray coating head on the gantry may be controlled by an operating system provided in the apparatus. Fourth and fifth axes of movement may be added to existing systems; however, such additional axes of movement are not automated and must be manually or pneumatically manipulated to desired positions.

### SUMMARY OF THE INVENTION

One aspect of the disclosure is directed to a spray coating apparatus for spraying material on a substrate. In one embodiment, the spray coating apparatus comprises a frame and a gantry coupled to the frame. The gantry may be configured to provide x-axis, y-axis and z-axis movement. A device is coupled to the gantry. The device may be configured to rotate about the z-axis and pivot about a point on the z-axis. A spray head is coupled to the device. A controller is coupled to the gantry and the spray head. The controller may be configured to control the automated movement of the gantry to provide x-axis, y-axis and z-axis movement and rotational and pivoting movement of the spray head.

Embodiments of the spray coating apparatus may further include a device having a housing, a motor coupled to the housing, and a drive shaft assembly coupled to the motor. The drive shaft assembly may be coupled to the spray head. The drive shaft assembly may include a drive shaft coupled to the motor and a bracket rotatably coupled to the housing. The bracket may be coupled to the spray head. In a certain embodiment, the substrate is an electronic circuit board. In another embodiment, the device may include a housing, a first motor coupled to the housing, and a first drive shaft assembly coupled to the first motor to provide rotational and linear motion, the first drive shaft assembly being coupled to the spray head to provide rotation about the z-axis and tilt about an intersecting axis. In yet another embodiment, the device may include a housing, a second motor coupled to the housing, and a second drive shaft assembly coupled to the second motor, the second drive shaft assembly being coupled to the spray head to provide pivoting about the point on the z-axis.

Another aspect of the disclosure is directed to a spray coating apparatus for spraying material on a substrate, the spray coating apparatus comprising a frame and a gantry coupled to the frame. In one embodiment, the gantry may be configured to provide x-axis, y-axis and z-axis movement. A device is coupled to the gantry, with the device being configured to rotate about the z-axis. A spray head is coupled to the device. A controller is coupled to the gantry and the spray head. In a certain embodiment, the controller may be configured to control the automated movement of the gantry to provide x-axis, y-axis and z-axis movement and rotational movement of the spray head.

Embodiments of the spray coating apparatus may further include a device having a housing, a motor coupled to the housing, and a drive shaft assembly coupled to the motor, the drive shaft assembly being coupled to the spray head. The drive shaft assembly may include a drive shaft coupled to the motor and a bracket rotatably coupled to the housing. The bracket may be coupled to the spray head. The substrate may be an electronic circuit board.

Yet another aspect of the disclosure is directed to a spray coating apparatus for spraying material on a substrate. In a particular embodiment, the spray coating apparatus may comprise a frame and a gantry coupled to the frame. The gantry may be configured to provide x-axis, y-axis and z-axis movement. A device is coupled to the gantry, with the device being configured to pivot about a point on the z-axis. A spray head is coupled to the device. A controller is coupled to the gantry and the spray head. The controller may be configured to control the automated movement of the gantry to provide x-axis, y-axis and z-axis movement and pivoting movement of the spray head.

Embodiments of the spray coating apparatus may further include a device having a housing, a motor coupled to the housing, and a drive shaft assembly coupled to the motor, the drive shaft assembly being coupled to the spray head. The drive shaft assembly may include a drive shaft coupled to the motor and a bracket pivotably coupled to the housing. The bracket may be coupled to the spray head. The substrate may be an electronic circuit board.

A further aspect of the disclosure is directed to a method for spraying material on a substrate. Embodiments of the method may comprise: positioning a spray head proximate to a substrate; and controlling the automated movement of the spray head to spray material on the substrate by moving the spray head in x-axis, y-axis and z-axis directions and by rotating the spray head about the z-axis.

Embodiments of the method may further include controlling the automated movement of the spray head to spray material on the substrate by pivoting the spray head about a point on the z-axis.

Another aspect of the disclosure is directed to an apparatus for applying material on a substrate. In one embodiment, the apparatus comprises a frame and a gantry coupled to the frame. The gantry may be configured to provide x-axis, y-axis and z-axis movement. A device is coupled to the gantry. The device may be configured to rotate about the z-axis and pivot about a point on the z-axis. An applicator is coupled to the device. A controller is coupled to the gantry and the applicator. The controller may be configured to control the automated movement of the gantry to provide x-axis, y-axis and z-axis movement and rotational and pivoting movement of the applicator.

Embodiments of the apparatus may further include a device having a housing, a motor coupled to the housing, and a drive shaft assembly coupled to the motor. The drive shaft assembly may be coupled to the applicator. The drive shaft assembly may include a drive shaft coupled to the motor and a bracket rotatably coupled to the housing. The bracket may be coupled to the applicator. In a certain embodiment, the substrate is an electronic circuit board. In another embodiment, the device may include a housing, a first motor coupled to the housing, and a first drive shaft assembly coupled to the first motor to provide rotational and linear motion, the first drive shaft assembly being coupled to the applicator to provide rotation about the z-axis and tilt about an intersecting axis. In yet another embodiment, the device may include a housing, a second motor coupled to the housing, and a second drive shaft assembly coupled to the second motor, the second drive shaft assembly being coupled to the applicator to provide pivoting about the point on the z-axis.

A further aspect of the disclosure is directed to a method for applying material on a substrate. Embodiments of the method may comprise: positioning an applicator proximate to a substrate; and controlling the automated movement of the applicator to apply material on the substrate by moving the applicator in x-axis, y-axis and z-axis directions and by rotating the applicator about the z-axis.

Embodiments of the method may further include controlling the automated movement of the applicator to apply material on the substrate by pivoting the applicator about a point on the z-axis.

The present disclosure will be more fully understood after a review of the following figures, detailed description and claims.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. Reference is made to the following drawing figures, which are incorporated herein by reference and in which:

FIG. 1 shows an embodiment of a spray coating apparatus;

FIG. 2 shows a perspective view of an embodiment of a gantry assembly of the spray coating apparatus;

FIG. 3 shows a perspective view of an embodiment of a spray coating head;

FIG. 4 shows an exploded perspective view of the spray coating head shown in FIG. 3;

FIG. 5 shows a perspective view of another embodiment of a spray coating head; and

FIG. 6 shows an exploded perspective view of the spray coating head shown in FIG. 5.

### DETAILED DESCRIPTION OF THE PREFERRED EMBODIMENTS

For the purposes of illustration only, and not to limit the generality, the present disclosure will now be described in detail with reference to the accompanying figures. This disclosure is not limited in its application to the details of construction and the arrangement of components set forth in the following description or illustrated in the drawings. The apparatus of embodiments disclosed herein is capable of other embodiments and of being practiced or being carried out in various ways. Also the phraseology and terminology used herein is for the purpose of description and should not be regarded as limiting. The use of “including,” “comprising,” “having,” “containing” “involving,” and variations thereof herein, is meant to encompass the items listed thereafter and equivalents thereof as well as additional items.

For purposes of illustration, embodiments of the present disclosure will now be described with reference to a spray coating apparatus used to spray coat material on an object. In certain embodiments, the material includes room temperature vulcanizing (RTV) silicone rubber, glues, sealants and other liquid coatings. However, other materials, including polymeric materials, may be employed with the apparatus disclosed herein. In other examples, solvent-based, water-based and solid materials may be employed. In other embodiments, objects may include, but are not limited to, electronic substrates, such as semiconductor wafers and printed circuit boards, medical devices, such as stents, and any other object or component requiring thin coatings of material. For example, and without limitation, objects used in the electronics, military, medical and automotive industries may be coated using the apparatus and methods disclosed herein. One skilled in the art will appreciate that embodiments of the present disclosure are not limited to spray coating apparatus capable of spraying protective materials onto electronic substrates, but rather, may be used in any application intended to coat objects.

In addition, although a particular spray coating apparatus platform is disclosed herein, the spray coating head of embodiments disclosed herein may be used with other types of platforms designed to manipulate spray coat heads. In one embodiment, the platform may include spray coating platforms sold by Specialty Coating Systems, Inc. of Indianapolis, Ind. under the trade name Precisioncoat.

In a certain embodiment, a spray coating apparatus includes a frame and a gantry coupled to the frame. As discussed above, the gantry is configured to provide x-axis, y-axis and z-axis movement. In a particular embodiment, a device is coupled to the gantry. The device may be configured to rotate about the z-axis and pivot about a point on the z-axis. The device is further configured to mount a spray head thereon. The spray head may be manipulated by a controller coupled to the gantry and the spray head. Specifically, the controller may be configured to control the automated movement of the gantry to provide x-axis, y-axis and z-axis movement and automated movement of the spray head to provide rotational and pivoting movement.

In one embodiment, the device includes a housing, a motor coupled to the housing, and a drive shaft assembly coupled to the motor, with the drive shaft assembly being coupled to the spray head. The drive shaft assembly may include a flexible drive shaft coupled to the motor and a bracket rotatably coupled to the housing. In another embodiment, the device includes a housing, a first motor coupled to the housing, and a first drive shaft assembly coupled to the first motor, with the first drive shaft assembly being coupled to the spray head to provide rotation about the z-axis. The device further includes a housing, a second motor coupled to the housing, and a second drive shaft assembly coupled to the housing and the second motor, with the second drive shaft assembly being coupled to the spray head to provide pivoting about the point on the z-axis.

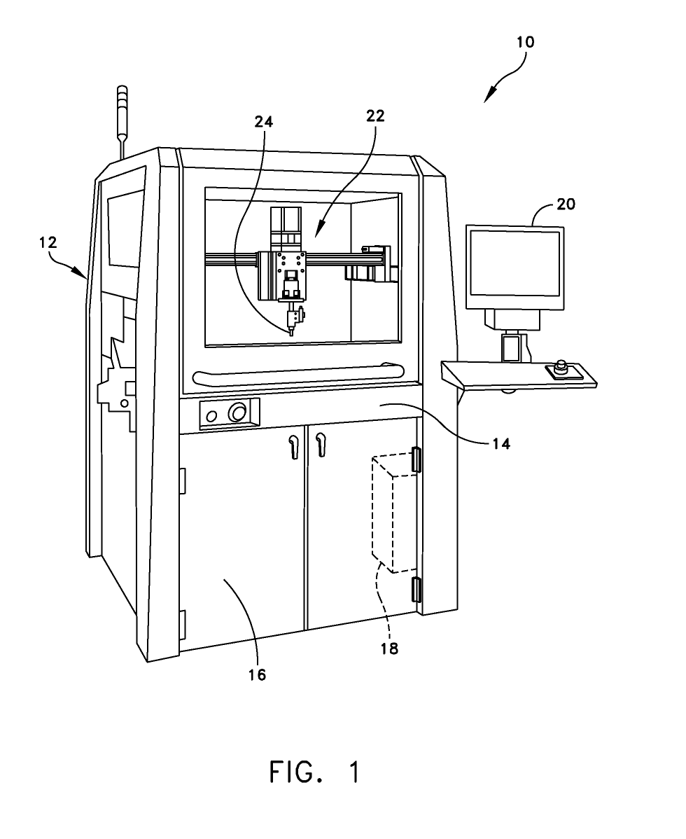

Referring now to the drawings, and more particularly to FIG. 1, there is generally indicated at 10 a spray coating apparatus of an embodiment of the disclosure. As shown, the spray coating apparatus 10 includes a housing, generally indicated at 12, having a frame 14 that supports components of the spray coating apparatus, and a cabinet 16. The components, in part, may include a controller 18 provided in the cabinet 16, a monitor 20 mounted on the frame 14 and connected to the controller, an x-axis, y-axis and z-axis gantry assembly generally indicated at 22 mounted on the frame, and a spray head 24 coupled to the gantry assembly. As discussed, each of these components may be suitably coupled directly and/or indirectly to the frame 14. In the shown embodiment, the spray head 24 may be mounted on the gantry assembly 22, which enables the spray head to be moved in the x-axis, y-axis and z-axis directions under the control of the controller 18.

In one embodiment, the controller 18 may be configured to use a personal computer having a suitable operating system (e.g., Windows XP® offered by Microsoft Corporation of Redmond, Wash.) with application specific software to control the operation of the spray coating apparatus 10. In a certain embodiment, an operator of the spray coating apparatus 10 may operate the apparatus either manually by manipulating a keyboard and a mouse provided with the monitor 20 or automatically by preprogramming the controller 18 by means of the keyboard and mouse through the monitor.

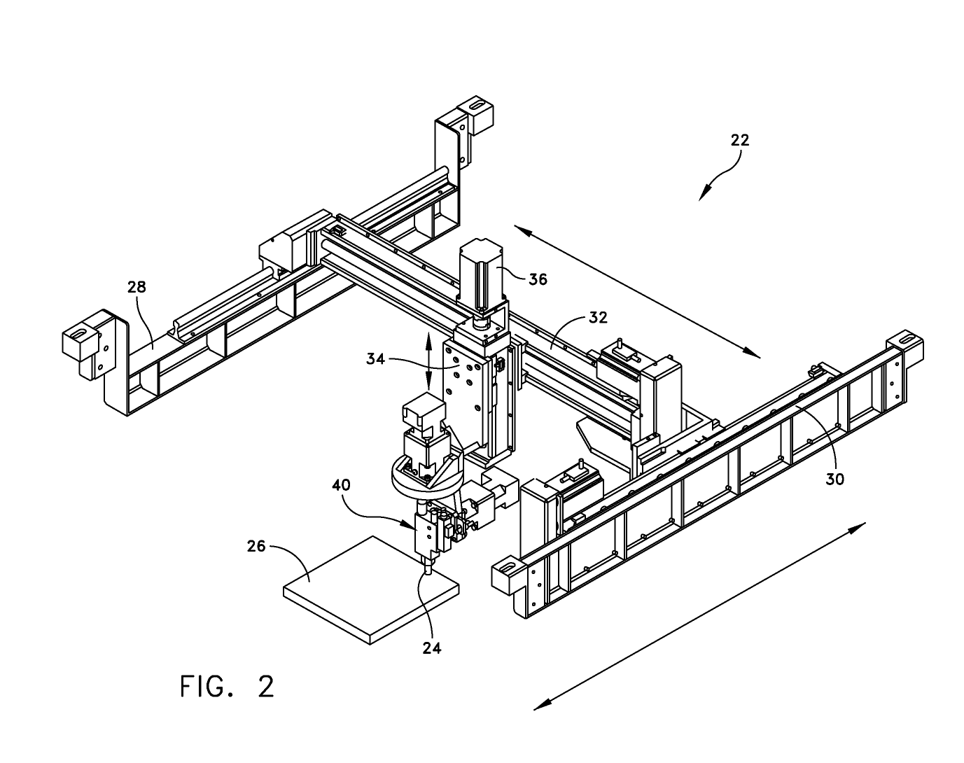

Turning now to FIG. 2, in a certain embodiment, the gantry assembly 22 can be moved using motors under the control of the controller 18 in the x-axis and y-axis directions to position the spray head 24 at predetermined locations over the object requiring spray coating, e.g., an electronic substrate 26. The substrate 26 may be suitably supported by a support mechanism or platform provided in the apparatus 10. The gantry assembly 22 may be configured to include a first side rail (linear actuator) 28, a second side rail (linear actuator) 30 and a beam 32 that extends between the two side rails. The first and second side rails 28, 30 are suitably mounted on the frame 14 of the spray coating apparatus 10. The beam 32 is configured to move in a y-axis direction along the side rails 28, 30 to achieve y-axis movement of the spray head 24. X-axis movement of the spray head 24 is achieved by a carriage 34 mounted on the beam 32. Specifically, the carriage 34 houses the spray head 24 and is configured to move along the length of the beam 32 in the x-axis direction to move the spray head over desired locations of the substrate 26. In a certain embodiment, movement of the gantry assembly 22 (i.e., movement of the beam 32 and the carriage 34) in the X-Y plane may be achieved by employing ball screw mechanisms driven by respective motors as is well known in the art.

The spray head 24, as mentioned above, is capable of achieving z-axis movement by means of a Z-drive mechanism, which is designated at 36 in FIG. 2. As shown, the carriage 34 is configured to include the Z-drive mechanism 36. The amount of z-axis movement may be preprogrammed by the controller 18 or determined by measuring the distance between the tip of the spray head 24 to the substrate 26.

As discussed above, the platform used to provide x-axis, y-axis and z-axis movement of the spray head 24 may include the Precisioncoat and/or Precisioncoat EL offered by Specialty Coating Systems, Inc. of Indianapolis, Ind. However, as will be apparent below, the device of embodiments described herein may be employed on any type of spray coating apparatus.

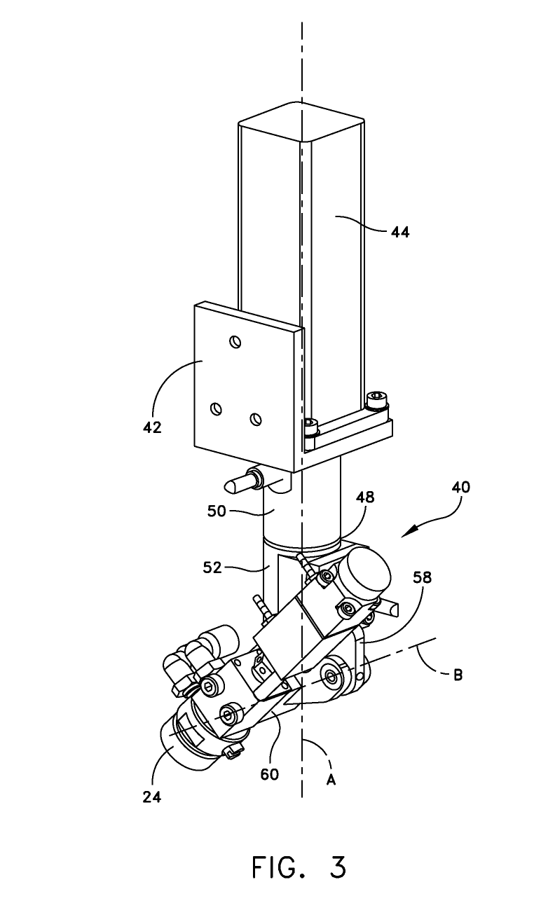

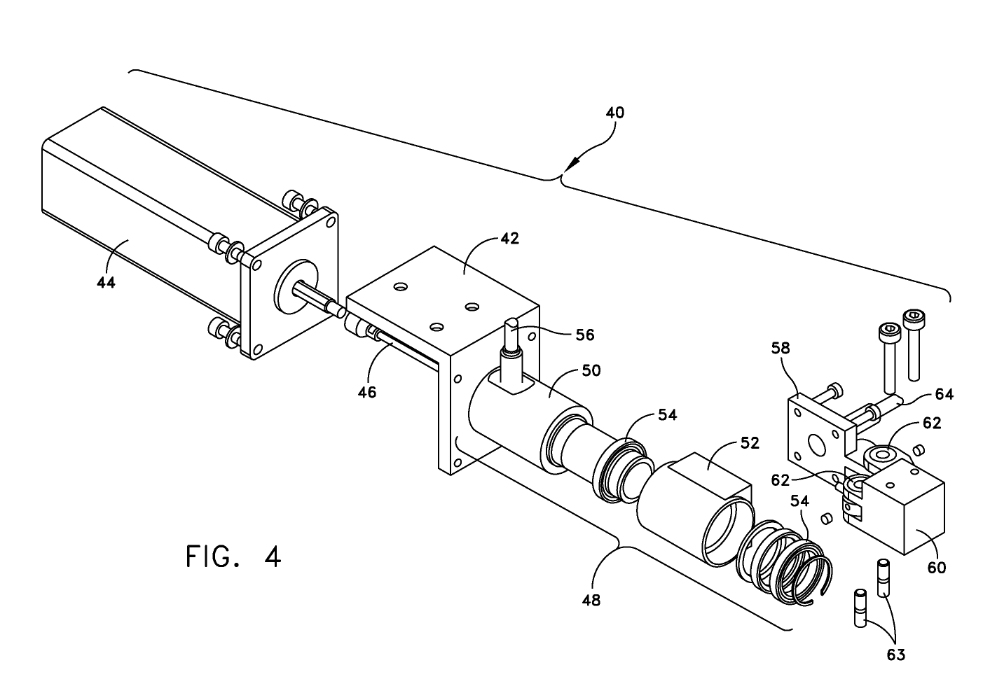

Referring to FIGS. 3 and 4, the spray head 24 is attached to the carriage 34 by means of a multi-axial movement device, generally indicated at 40, configured to provide rotational and pivoting movement of the spray head. Specifically, the device 40 is coupled to the controller 18 to provide automated control of the device for rotating and pivoting the spray head 24 to desired positions. Thus, the spray coating apparatus 10 incorporating the device 40 of embodiments disclosed herein is capable of providing automated positioning of the spray head so that the spray head is in an optimal position to precisely perform spray coating operations.

As shown best in FIG. 4, the device 40 includes an L-shaped bracket 42, which is secured to the carriage 34. The L-shaped bracket 42 is configured to mount a motor 44, which drives rotational and pivoting motion of the spray head 24 mounted on the device 40 in the manner described below. In the shown embodiment, screw fasteners may be provided to mount the motor 44 onto the L-shaped bracket 42. In one embodiment, the motor 44 may comprise a linear actuator sold by Hayden Switch and Instrument, Inc. of Waterbury, Conn. The motor 44 includes a shaft portion that is suitably connected to a flexible shaft 46, which is captured by a bearing assembly 48 to provide rotation about axis A.

Specifically, the bearing assembly 48 includes a first body 50 fixedly mounted on or otherwise secured to the L-shaped bracket 42. A second body 52 is rotatably connected to the first body 50 to provide the desired rotational movement. The arrangement is such that the motor 44, under the control of the controller 18, drives the rotational movement of the second body 52 with respect to the first body 50. Bearings, each indicated at 54, are disposed between the first and second bodies 50, 52 to facilitate relevant movement between the two bodies. A sensor 64, coupled to the controller 18, is provided to determine the rotational position of body 52 with respect to body 50.

Still referring to FIGS. 3 and 4, a first pivot bracket 58 is mounted on the second body 52 (as by screw fasteners). The first pivot bracket 58 is configured to receive a shaft member (not shown), which engages the flexible shaft 46 to provide automated pivoting movement about axis B (see FIG. 3). The arrangement is such that a motor shaft turns about its centerline to produce rotational motion of flexible shaft 46 and extends and retracts to provide tilt about axis B. The motor 44 may be referred to as a “dual motion motor” in that the flexible shaft both rotates and extends and retracts. This motion usually requires both a motor (rotation) and an actuator (linear). Specifically, the first pivot bracket 58 is pivotally coupled to a second pivot bracket 60, which is configured to mount the spray head thereon. The first pivot bracket 58 is pivotably secured to the second pivot bracket 60 by a pair of bearings, each indicated at 62, which are sized to receive a pair of small shaft members 63. The arrangement is such that the motor 44, under the control of the controller 18, drives the pivoting movement of the second pivot bracket 60 with respect to the first pivot bracket 58 about axis B. A sensor 56, coupled to the controller 18, is provided to determine the position of the shaft member.

During operation, when spraying material on a substrate 26, the spray head 24 is positioned proximate to the substrate. The controller 18 controls the automated movement of the spray head 24 to spray material on the substrate by moving the spray head in x-axis, y-axis and z-axis directions by means of the gantry assembly 22 and by rotating the spray head about axis A by means of the device 40. The controller 18 also controls the automated movement of the spray head 24 to spray material on the substrate 26 by pivoting the spray head about axis B, which is a point on the z-axis defined by the location of the first and second pivot brackets 58, 60.

The spray head 24 may be configured to spray particular materials. For example, the spray head may be configured with a particular type of nozzle suitable for spraying a conformal coating material. The provision of the device 40 enables the spray head to be optimally positioned, which is particularly beneficial for applications requiring precise spraying operations. In one embodiment, the spray head may be an assembly of separate components or provided by a suitable manufacturer, such as EFD, Inc. of East Providence, R.I. or Graco Inc. of North Canton, Ohio.

In certain embodiments, the bearing assembly 48, in addition to the first body 50, the second body 52 and the bearings 54, which are identified in FIG. 4, may include other components. For example, the bearing assembly may include a combination of springs, spacers and snap rings to enable or otherwise facilitate the relative rotation of the first and second bodies.

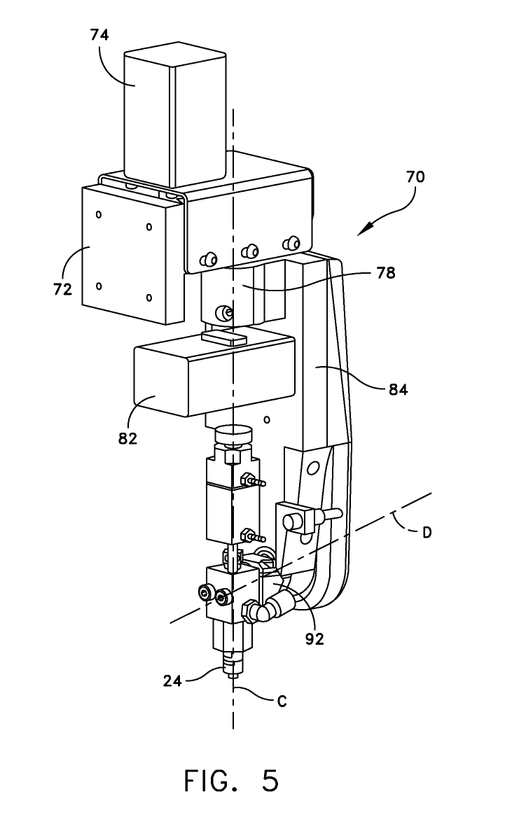

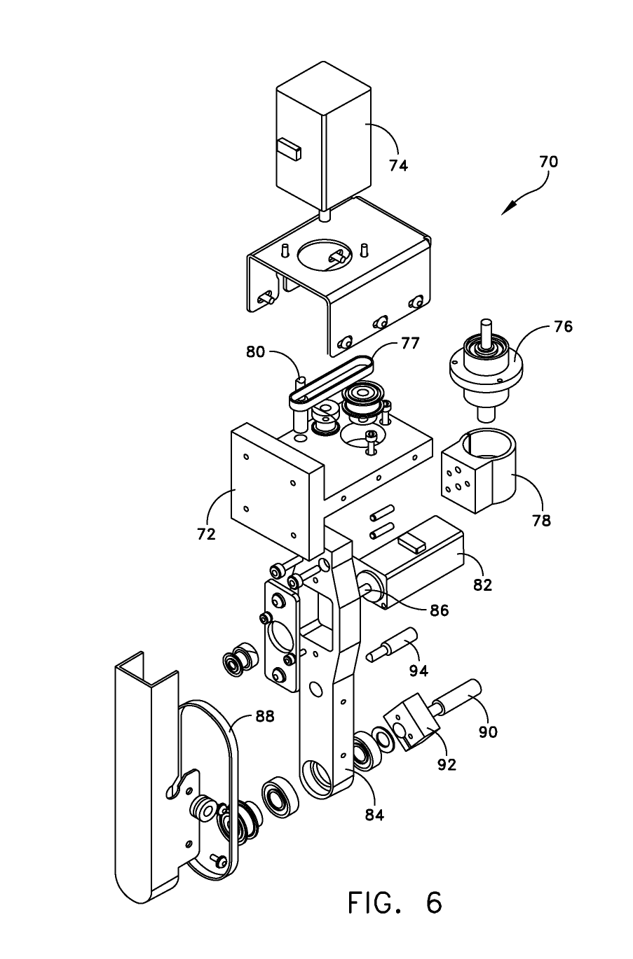

Turning now to FIGS. 5 and 6, in another embodiment, the spray head 24 is attached to the carriage 34 by means of device, generally indicated at 70, which is also configured to provide rotational and pivoting movement of the spray head. As shown, device 70 is similar to device 40, but operates differently in that the device 70 incorporates two separate motors to drive the rotational and pivoting movement of the spray head, respectively, in the manner described below. Specifically, the device 70 is coupled to the controller 18 to provide automated control of the device to rotate and pivot the spray head 24 to desired positions. Thus, as with device 40, the spray coating apparatus 10 incorporating the device 70 is capable of providing automated positioning of the spray head 24 to precisely perform spray coating operations.

As shown, a T-shaped bracket 72 secures the device 70 to the carriage 34. The T-shaped bracket 72 is configured to mount a first motor 74, which drives the rotational motion of the spray head 24. In one embodiment, the first motor 74 may be supplied by Intelligent Motion Systems, Inc. of Marlborough, Conn. The first motor 74 is connected to a shaft assembly 76 by means of a belt 77. As shown, the shaft in shaft assembly 76 is coupled to a bearing body 78 to provide rotation about axis C. The arrangement is such that the first motor 74, under the control of the controller 18, drives the rotational movement of the bearing body 78 with respect to the T-shaped bracket 72. A sensor 80, coupled to the controller 18, is provided to determine the rotational position of the device 70.

Still referring to FIGS. 5 and 6, a second motor 82 is mounted on an elongate bracket 84, which is secured to the bearing body 78 (as by screw fasteners). The second motor 82 includes a shaft 86 that drives a belt 88 connected to a shaft member 90. As shown, a clamping bracket 92 is secured to the shaft member 90, the clamping bracket being configured to have the spray head 24 mounted thereon. The arrangement is such that the second motor 82, under the control of the controller 18, drives the pivoting movement of the clamping bracket 92 with respect to the elongate bracket 84. A sensor 94, coupled to the controller 18, is provided to determine the position of the shaft member 90.

During operation, when spraying material on a substrate 26, such as an electronic substrate, the spray head 24 is positioned proximate to the substrate. The controller 18 controls the automated movement of the spray head 24 to spray material on the substrate 26 by moving the spray head in x-axis, y-axis and z-axis directions by means of the gantry assembly 22. The controller 18, by means of controlling the operation of the first motor 74, controls rotational movement about axis C. Similarly, the controller 18, by means of controlling the operation of the second motor 82, controls pivoting movement about axis D.

As with device 40, the spray head 24 mounted on device 70 may be configured to spray particular materials. In addition, although belt drives are shown to drive the rotational and pivoting movement of the device 70, it should be understood that other types of drive mechanisms may be employed. For example, gear drive mechanism may be used or the rotation may come directly off of the motor shaft or the shaft of an intermediate gear reducer mechanism.

In other embodiments, the spray head 24 may be replaced with a different applicator, such as a dispenser, for applying materials onto a substrate. For example, the applicator may include a dispenser for dispensing more viscous materials.

Thus, it should be observed that the devices disclosed herein are particularly suited for positioning a spray head in a desired position without having to manually manipulate the spray head. The controller may be programmed to move the gantry assembly and the device (either device 40 or device 70) to position the spray head. The automated movement of the spray head saves time as well as enables the operation to exactly position the spray head for optimal operation.

Having thus described at least one embodiment of the present disclosure, various alternations, modifications and improvements will readily occur to those skilled in the art. Such alterations, modifications and improvements are intended to be within the scope and spirit of the disclosure. Accordingly, the foregoing description is by way of example only and is not intended to be limiting. The disclosure's limit is defined only in the following claims and equivalents thereto.

What is claimed is:

1. A spray coating apparatus for spraying material on a substrate, the spray coating apparatus comprising:
a frame;
a gantry coupled to the frame, the gantry being configured to provide x-axis, y-axis and z-axis movement;
a device coupled to the gantry, the device being configured to rotate about the z-axis and pivot about a point on the z-axis;
a spray head coupled to the device; and
a controller coupled to the gantry and the spray head, the controller being configured to control the automated movement of the gantry to provide x-axis, y-axis and z-axis movement and rotational and pivoting movement of the spray head.

2. The spray coating apparatus of claim 1, wherein the device comprises
a housing,
a motor coupled to the housing, and
a drive shaft assembly coupled to the motor, the drive shaft assembly being coupled to the spray head.

3. The spray coating apparatus of claim 2, wherein the drive shaft assembly includes a drive shaft coupled to the motor and a bracket rotatably coupled to the housing, the bracket being coupled to the spray head.

4. The spray coating apparatus of claim 1, wherein the substrate is an electronic circuit board.

5. The spray coating apparatus of claim 1, wherein the device comprises
a housing,
a first motor coupled to the housing, and
a first drive shaft assembly coupled to the first motor to provide rotational and linear motion, the first drive shaft assembly being coupled to the spray head to provide rotation about the z-axis and tilt about an intersecting axis.

6. The spray coating apparatus of claim 5, wherein the device further comprises
a second motor coupled to the housing, and
a second drive shaft assembly coupled to the second motor, the second drive shaft assembly being coupled to the spray head to provide pivoting about the point on the z-axis.

7. A spray coating apparatus for spraying material on a substrate, the spray coating apparatus comprising:
a frame;
a gantry coupled to the frame, the gantry being configured to provide x-axis, y-axis and z-axis movement;
a device coupled to the gantry, the device being configured to rotate about the z-axis;
a spray head coupled to the device; and
a controller coupled to the gantry and the spray head, the controller being configured to control the automated movement of the gantry to provide x-axis, y-axis and z-axis movement and rotational movement of the spray head.

8. The spray coating apparatus of claim 7, wherein the device comprises
a housing,
a motor coupled to the housing, and
a drive shaft assembly coupled to the motor, the drive shaft assembly being coupled to the spray head.

9. The spray coating apparatus of claim 8, wherein the drive shaft assembly includes a drive shaft coupled to the motor and a bracket rotatably coupled to the housing, the bracket being coupled to the spray head.

10. The spray coating apparatus of claim 7, wherein the substrate is an electronic circuit board.

11. A spray coating apparatus for spraying material on a substrate, the spray coating apparatus comprising:
a frame;
a gantry coupled to the frame, the gantry being configured to provide x-axis, y-axis and z-axis movement;
a device coupled to the gantry, the device being configured to pivot about a point on the z-axis;
a spray head coupled to the device; and
a controller coupled to the gantry and the spray head, the controller being configured to control the automated movement of the gantry to provide x-axis, y-axis and z-axis movement and pivoting movement of the spray head.

12. The spray coating apparatus of claim 11, wherein the device comprises
a housing,
a motor coupled to the housing, and
a drive shaft assembly coupled to the motor, the drive shaft assembly being coupled to the spray head.

13. The spray coating apparatus of claim 12, wherein the drive shaft assembly includes a drive shaft coupled to the motor and a bracket pivotably coupled to the housing, the bracket being coupled to the spray head.

14. The spray coating apparatus of claim 11, wherein the substrate is an electronic circuit board.

15. A method for spraying material on a substrate, the method comprising:
positioning a spray head proximate to a substrate; and
controlling the automated movement of the spray head to spray material on the substrate by moving the spray head in x-axis, y-axis and z-axis directions and by rotating the spray head about the z-axis.

16. The method of claim 15, further comprising controlling the automated movement of the spray head to spray material on the substrate by pivoting the spray head about a point on the z-axis.

17. An apparatus for applying material on a substrate, the apparatus comprising:
a frame;
a gantry coupled to the frame, the gantry being configured to provide x-axis, y-axis and z-axis movement;
a device coupled to the gantry, the device being configured to rotate about the z-axis and pivot about a point on the z-axis;
an applicator coupled to the device; and
a controller coupled to the gantry and the applicator, the controller being configured to control the automated movement of the gantry to provide x-axis, y-axis and z-axis movement and rotational and pivoting movement of the applicator.

18. The apparatus of claim 17, wherein the device comprises
a housing,
a motor coupled to the housing, and
a drive shaft assembly coupled to the motor, the drive shaft assembly being coupled to the applicator.

19. The apparatus of claim 18, wherein the drive shaft assembly includes a drive shaft coupled to the motor and a bracket rotatably coupled to the housing, the bracket being coupled to the applicator.

20. The apparatus of claim 17, wherein the device comprises
a housing,
a first motor coupled to the housing, and
a first drive shaft assembly coupled to the first motor to provide rotational and linear motion, the first drive shaft assembly being coupled to the applicator to provide rotation about the z-axis and tilt about an intersecting axis.

21. The apparatus of claim 20, wherein the device further comprises
a second motor coupled to the housing, and
a second drive shaft assembly coupled to the second motor, the second drive shaft assembly being coupled to the applicator to provide pivoting about the point on the z-axis.

22. A method for applying material on a substrate, the method comprising:
positioning an applicator proximate to a substrate; and
controlling the automated movement of the applicator to apply material on the substrate by moving the applicator in x-axis, y-axis and z-axis directions and by rotating the applicator about the z-axis.

23. The method of claim 22, further comprising controlling the automated movement of the applicator to apply material on the substrate by pivoting the applicator about a point on the z-axis.
